(19) United States
(12) Patent Application Publication
(10) Pub. No.: US 2015/0249158 A1
(43) Pub. Date: Sep. 3, 2015

(54) SEMICONDUCTOR STRUCTURE AND METHOD FOR MANUFACTURING THE SAME

(71) Applicant: United Microelectronics Corp., Hsinchu (TW)

(72) Inventors: Wei Cheng, Singapore (SG); Hua-Kuo Lee, Taipei City (TW); Ching-Long Tsai, Taipei City (TW); Chi Ren, Singapore (SG); Cheng-Yuan Hsu, Hsinchu City (TW)

(73) Assignee: United Microelectronics Corp., Hsinchu (TW)

(21) Appl. No.: 14/194,957

(22) Filed: Mar. 3, 2014

(51) Int. Cl. H01L 29/788; H01L 21/3213; H01L 29/40

(52) U.S. Cl. CPC H01L 29/7883; H01L 29/7885; H01L 29/401; H01L 21/32133

(57) ABSTRACT

A semiconductor structure and a method for manufacturing the same are provided. The semiconductor structure comprises a substrate, a first gate structure, a second gate electrode, a third gate electrode and a protective layer. The first gate structure comprises a first gate electrode disposed on the substrate and a first gate dielectric covering the first gate electrode. The second gate electrode is disposed on and electrically isolated from the first gate electrode. The first gate structure has an extending portion relative to the second gate electrode. The third gate electrode is disposed adjacent to and electrically isolated from the first gate electrode and the second gate electrode. The third gate has an extending portion between a lower surface of the protective layer and an upper surface of the extending portion of the first gate structure.

### BACKGROUND

1. Technical Field

The disclosure relates to a semiconductor structure and a method for manufacturing the same.

2. Description of the Related Art

Engineers in the semiconductor field have been attempted to decrease the sizes of semiconductor devices. In the late 20th century, the semiconductor devices had sizes of micro-scale. Nowadays, 15 nm node is being researched. As the sizes of semiconductor devices become smaller, in particular since the development of 90 nm node, some problems resulted from the decreased sizes are encountered. For example, some elements of the devices may not be robust enough for enduring sequential process steps, or may not function as protectors for other elements during the process steps anymore. In addition, the deterioration due to the defects may become more critical. These problems must be overcome for further development of smaller nodes.

### SUMMARY

The disclosure is directed to a semiconductor structure and a method for manufacturing the same. The semiconductor structure and the method for manufacturing the same are developed to overcome some of the problems resulted from the decreased device sizes.

According to some embodiment, a semiconductor structure comprises a substrate, a first gate structure, a second gate electrode, a third gate electrode and a protective layer. The first gate structure comprises a first gate electrode disposed on the substrate and a first gate dielectric covering the first gate electrode. The first gate structure has an extending portion. The second gate electrode is disposed on and electrically isolated from the first gate electrode. The extending portion of the first gate structure extends beyond a sidewall of the second gate electrode. The third gate electrode is disposed adjacent to and electrically isolated from the first gate electrode and the second gate electrode. The third gate electrode has an extending portion. The extending portion of the third gate electrode is between a lower surface of the protective layer and an upper surface of the extending portion of the first gate structure.

According to some embodiment, a method for manufacturing a semiconductor structure, which has a cell region and a periphery region, comprises the following steps. First of all, a substrate is provided. A stack is formed on the substrate in the cell region. The stack comprises a first gate structure and a second gate electrode for a memory cell, wherein the first gate structure comprises a first gate electrode formed on the substrate and a first gate dielectric covering the first gate electrode, the second gate electrode is disposed on the first gate electrode, and the first gate structure has an extending portion extending beyond a sidewall of the second gate electrode. A conductive layer is formed on the substrate and covers the stack. Then, part of the conductive layer is removed to form a third gate electrode adjacent to the first gate structure and the second gate electrode, wherein the third gate electrode has an extending portion. After that, a protective layer is formed on the third gate electrode such that the extending portion of the third gate electrode is between a lower surface of the protective layer and an upper surface of the extending portion of the first gate structure.

According to some embodiment, a method for manufacturing a semiconductor structure comprises the following steps. First of all, a substrate is provided. A stack is formed on the substrate. The stack comprises a first gate structure and a second gate electrode for a memory cell, wherein the first gate structure comprises a first gate electrode formed on the substrate and a first gate dielectric covering the first gate electrode, the second gate electrode is disposed on the first gate electrode, and the first gate structure has an extending portion extending beyond a sidewall of the second gate electrode. Then, a third gate electrode is formed adjacent to the first gate structure and the second gate electrode, wherein the third gate electrode has an extending portion. After that, a protective layer is formed on the third gate electrode such that the extending portion of the third gate electrode is between a lower surface of the protective layer and an upper surface of the extending portion of the first gate structure.

### BRIEF DESCRIPTION OF THE DRAWINGS

FIGS. 1A-1G schematically illustrate steps of a method for manufacturing a semiconductor structure according to one embodiment.

FIG. 2 shows a semiconductor structure according to one embodiment.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

In the following description, to facilitate understanding of the semiconductor structure and the manufacturing method therefor according to this invention, an embedded flash (eFlash) with the split-gate structure, among other semiconductors, will be exemplarily described. The embedded non-volatile memories, such as eFlash, embedded EEPROM (eEEPROM) and the like, are used in modern consumer products to satisfy the requirements of higher diversification while lower volume of units.

A typical split-gate flash may comprise a floating gate, a control gate and an erase gate. The floating gate is disposed on a channel region formed in a substrate. The control gate is disposed on the floating gate. The erase gate is disposed adjacent to the floating gate and the control gate. For programming the split-gate flash, hot electron injection may be used. A lateral electric field is applied to the channel. Meanwhile, a high voltage is applied to the control gate to form a vertical electric field. As such, electrons may be driven by the electric fields and trapped in the floating gate. For erasing the split-gate flash, Fowler-Nordheim (F-N) tunneling may be used. A high voltage is applied to the erase gate to induce F-N tunneling from the floating gate to the erase gate. To facilitate the F-N tunneling, the floating gate may be configured to have a corner protruding toward the erase gate. By such configuration, the electric field is concentrated at the corner, thus enhances the tunneling effect.

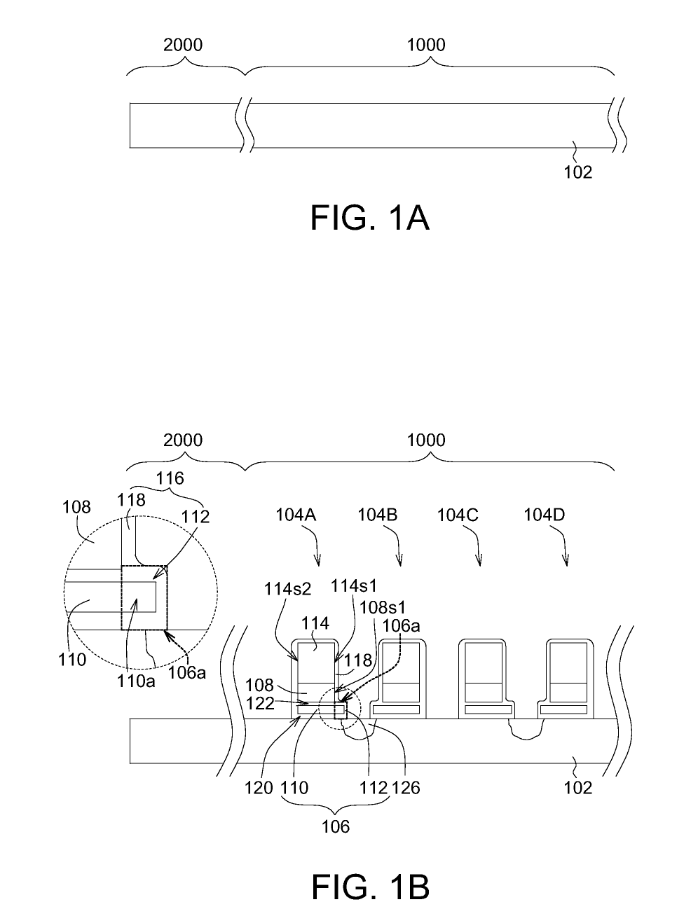

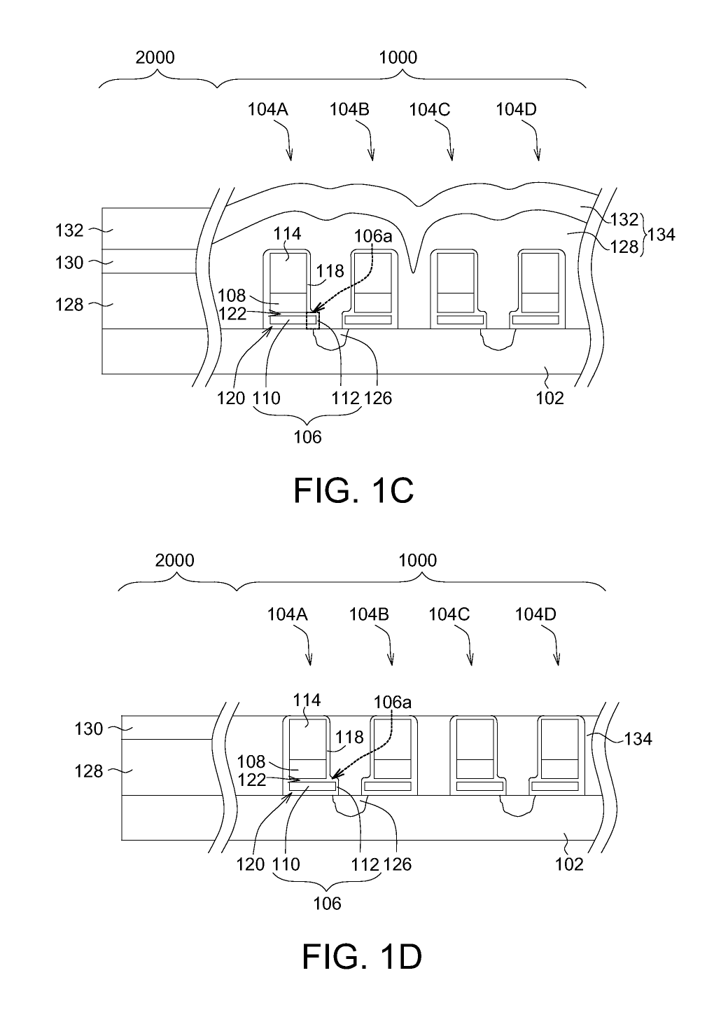

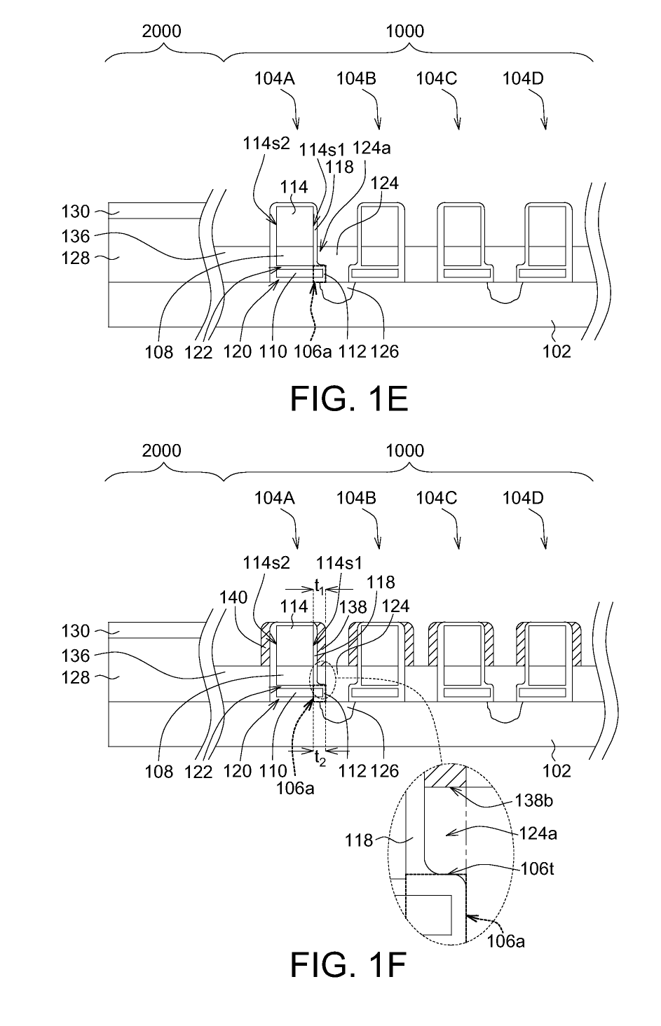

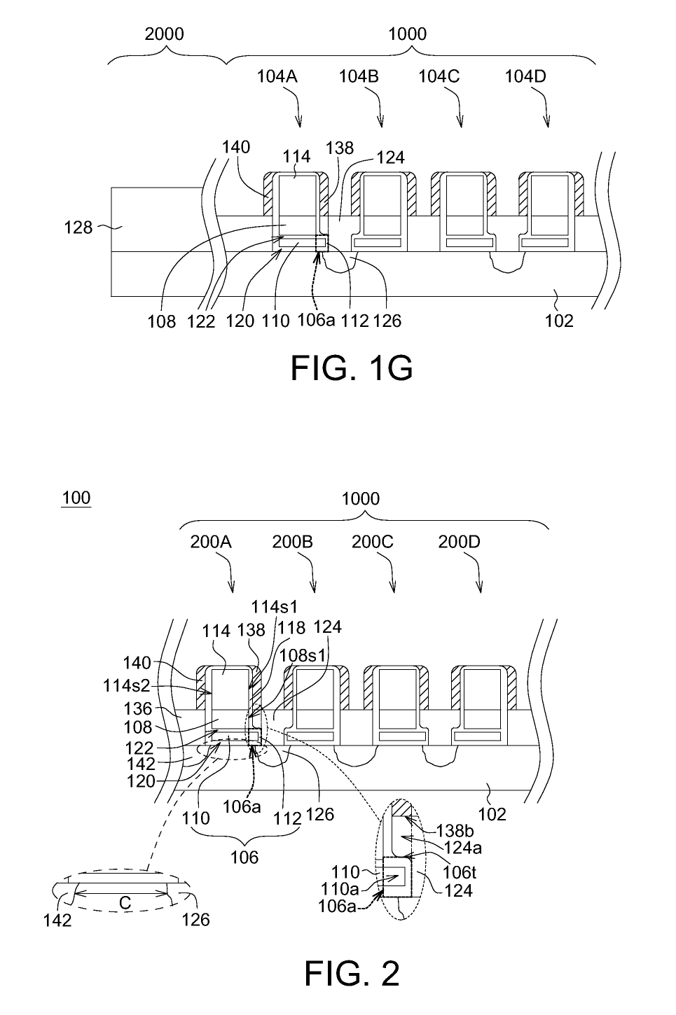

Now referring to FIGS. 1A-1G, a method for manufacturing a semiconductor structure according to one embodiment is illustrated. Here, the semiconductor structure may be a structure for a split-gate flash. For clarity, some elements and reference numerals may be removed from some of the drawings.

The semiconductor structure may have a cell region 1000 and a periphery region 2000. At first, a substrate 102 is provided, as shown in FIG. 1A. The substrate 102 may be a substantially single crystalline substrate, such as a single crystalline silicon substrate of p-type or n-type.

Referring to FIG. 1B, one or more stacks 104A-104D are formed on the substrate 102 in the cell region 1000. While four stacks 104A-104D are shown in FIG. 1B, the number of the stacks is not limited thereto. Adjacent two of the stacks, such as stacks 104A and 104B, are disposed reflectional symmetrically. For simplify, following description will be focused on the stack 104A. However, the same process steps will be applied to all of the stacks, and similar structures may be formed over the whole cell region 1000 at each step.

The stack 104A comprises a first gate structure 106 and a second gate electrode 108 for a memory cell. The first gate structure comprises a first gate electrode 110 formed on the substrate 102 and a first gate dielectric 112 covering the first gate electrode 110. The second gate electrode 108 is disposed on the first gate electrode 110. More specifically, the second gate electrode 108 disposed on the first gate electrode 110 is spatially separated and electrically isolated from the first gate electrode 110. The second gate electrode 108 has a sidewall 108s1. The first gate structure 106 has an extending portion 106a relative to the second gate electrode 108. More specifically, the extending portion 106a extends beyond the sidewall 108s1 of the second gate electrode 108. In the case that the semiconductor structure is configured for a split-gate flash, the first gate electrode 110 may be a floating gate, and the second gate electrode 108 may be a control gate. The first gate electrode 110 has a protruding portion 110a, which protrudes relative to the second gate electrode 108, so as to provide the corner for enhancing the erase process. The first gate dielectric 112 covering the first gate electrode 110 particularly covers the protruding portion 110a.

The stack 104A may further comprise a top layer 114 disposed on the second gate electrode 108. The top layer 114 may be used as a hard mask for the second gate electrode 108 in the process steps. In one embodiment, the top layer 114 may be a composite layer, such as a nitride-oxide-nitride composite layer. The top layer 114 has two opposite sidewalls 114s1 and 114s2.

At the step of forming the stack 104A, a gate dielectric layer 116 comprising the first gate dielectric 112 and extending along the sidewall 108s1 of the second gate electrode 108 and the sidewall 114s1 of the top layer 114 may be formed. The first gate dielectric 112 spatially separates and electrically isolates a third gate electrode 124 (shown in FIG. 1E) to be formed in the following steps from the first gate electrode 110. The gate dielectric layer 116 may further comprise a second gate dielectric 118 on the sidewall 108s1 so as to spatially separate and electrically isolate the second gate electrode 108 from the third gate electrode 124. The first gate dielectric 112 and the second gate dielectric 118 may comprise oxide. For example, the gate dielectric layer 116 comprising the first gate dielectric 112 and the second gate dielectric 118 may be an oxide layer or an oxide-nitride-oxide composite layer. The second gate dielectric 118 may further extend upward along the sidewall 114s1 of the top layer 114. The gate dielectric layer 116 may connect with a third gate dielectric 120 and a fourth gate dielectric 122 of the stack 104A. The third gate dielectric 120 spatially separates and electrically isolates the first gate electrode 110 from the substrate 102, particularly from a channel region C (shown in FIG. 2) formed in the substrate 102. The fourth gate dielectric 122 spatially separates and electrically isolates the second gate electrode 108 from the first gate electrode 110. The third gate dielectric 120 and the fourth gate dielectric 122 may be oxide layers or oxide-nitride-oxide composite layers. Similarly, a dielectric layer, which may be used to isolate the first and second gate electrodes 110, 108 from a word line to be formed in the following steps (such as the word line 136 shown in FIG. 1E), formed opposite to the gate dielectric layer 116 may be oxide layers or oxide-nitride-oxide composite layers.

The method may further comprise a step of forming a first doped region 126. The first doped region 126 is formed in the substrate 102 near the extending portion 106a. Two adjacent stacks, such as stacks 104A and 104B, may share a first doped region 126.

After the step illustrated in FIG. 1B, a third gate electrode 124 is formed adjacent to the first gate structure 106 and the second gate electrode 108, as illustrated in FIGS. 10-1E.

Referring to FIG. 10, a first conductive layer 128, a cap layer 130 and a second conductive layer 132 are sequentially formed on the substrate 102. The first conductive layer 128 is formed on the substrate 102 in the cell region 1000 and the periphery region 2000. The first conductive layer 128 covers the stacks 104A-104D. The cap layer 130 is formed on the first conductive layer 128 in the periphery region 2000. In one embodiment, the cap layer 130 may be formed by depositing a cap material on the whole structure 102, comprising both the cell region 1000 and the periphery region 2000, and then removed the part formed in the cell region 1000. The cap material may be an oxide. The second conductive layer 132 is formed on the first conductive layer 128 in the cell region 1000 and the periphery region 2000. As such, in the cell region 1000, a conductive layer 134 composed of the first conductive layer 128 and the second conductive layer 132 is formed on the substrate 102 covering the stacks 104A-104D. While in the periphery region 2000, a tri-layered architecture is formed.

Then, part of the conductive layer 134 is removed to form the third gate electrode 124. Referring to FIG. 1D, at least the first conductive layer 128 and the second conductive layer 132 in the cell region 1000 and the second conductive layer 132 in the periphery region 2000 are planarized, for example, by chemical-mechanical polish. In one exemplary embodiment that silicon oxide is the material at top surfaces of the cap layer 130 and the stacks 104A-104D and the conductive layer 134 is fabricated from poly-Si, the removing rate of poly-Si may be adjusted to larger than that of silicon oxide by choosing a suitable etchant for the planarization process. As such, the planarization process may stop when the top surfaces of the stacks 104A-104D are exposed. The second conductive layer 132 in the periphery region 2000 may be completely removed by the planarizing step.

Referring to FIG. 1E, the first conductive layer 128 and the second conductive layer 132 in the cell region 1000 are etched, for example, by a suitable wet etching process. By controlling the removing rate of the conductive layer larger than that of the dielectric layers, the conductive layer may be optionally removed, while the dielectric layers are remained. Specifically, the portion of the gate dielectric layer 116 on the sidewall 114s1 of the top layer 114 may be exposed from the conductive layer 134 by this etching step. The third gate electrode 124 is therefore formed in the cell region 1000 adjacent to the first gate structure 106 and the second gate electrode 108. The third gate electrode 124 is formed adjacent to and electrically isolated from the first gate electrode 110 and the second gate electrode 108. The third gate electrode 124 has an extending portion 124a overhanging on the protruding portion 110a of the first gate electrode 110. In the case that the semiconductor structure is configured for a split-gate flash, the third gate electrode 124 may be an erase gate. Two adjacent stacks, such as stacks 104A and 104B, may share a third gate electrode 124.

Here, a word line 136 may be formed simultaneously with the third gate electrode 124. The word line 136 is formed adjacent to the first gate electrode 110 and the second gate electrode 108 and opposite to the third gate electrode 124.

In this etching step, part of the cap layer 130 in the periphery region 2000 may also be etched. However, most part of the cap layer 130 will remain and protect the first conductive layer 128 thereunder.

Now referring to FIG. 1F, a protective layer 138 is formed on the third gate electrode 124 overlapping the extending portion 106a of the first gate structure 106. The protective layer 138 overlaps the extending portion 106a, such that the extending portion 124a of the third gate electrode 124 is between a lower surface 138b of the protective layer 138 and an upper surface 106t of the extending portion 106a of the first gate structure 106. In one embodiment, the protective layer 138 may be in direct contact with the third gate electrode 124.

Specifically, the step of forming the protective layer 138 may comprise depositing a protective material in the cell region 1000 covering the stacks 104A-104D and the third gate electrode 124, and removing the undesired part of the protective material, for example, by dry etching. The protective material may comprise silicon nitride (SiN), silicon oxynitride (SiON), silicon carbide (SiC), or silicon carbonitride (SiCN). The protective material may comprise the material the top layer 114 used. Alternatively, the protective material is a material having an etching rate substantially the same as that of the top layer 114, i.e., the etching rate ratio is 0.8 to 1.2, and preferably is 1. In particular, SiN may be used to form the protective layer 138.

The conventional manufacturing method does not comprise this protective layer-forming step. As the reduction of the flash sizes, the thicknesses of the floating gate, the control gate, the erase gate and the like are all decreased. From the 55 nm node, the erase gate and a corresponding gate dielectric are not thick enough anymore to protect the protruding portion of the floating gate from damage that may be produced by following manufacturing steps, such as ion implantation. In addition, divots may be formed during an oxide etching step, such as a removing step for the cap layer, thus the oxides used as gate dielectrics in the flash will be hurt and thereby further deteriorate the floating gate damage, and an undesired electric field may be produced at the divot portion and disadvantageously affect the flash performance. For example, in a split-gate flash of 55 nm node, the floating gate may be 400 Å thick, the erase gate may be 1000 Å thick, so as the gate dielectric between the erase gate and the control and floating gates. If a divot with about 200 Å-250 Å depth is formed in the gate dielectric, a total thickness of the layer(s) that can be used as a protector of the floating gate during a following implantation process may be just 350 Å. In the manufacturing method according to this invention, since the protective layer 138 is formed overlapping the extending portion 106a of the first gate structure 106, it can protect the protruding portion 110a in the following process steps.

In one embodiment, the protective layer 138 may be formed along the sidewall 114s1 of the top layer 114, which is close to the third gate electrode 124. More specifically, the protective layer 138 may be formed on the portion of the gate dielectric layer 116 that is exposed from the conductive layer 134, i.e., the portion of the second gate dielectric 118 formed on the sidewall 114s1. The protective layer 138 may be in direct contact with the second gate dielectric 118. For fully protecting the protruding portion 110a, the protective layer 138 is preferably thick enough to cover the edge of the protruding portion 110a. A total thickness t₁ of the second gate dielectric 118 and the protective layer 138 may be equal to or larger than a total thickness t₂ of the extending portion 106a of the first gate structure 106, so as to protect the protruding portion 110a from damaged by the following process steps in a better way. For example, the thickness of the protective layer 138 may be 200 Å or more.

Here, another protective layer 140 may be formed simultaneously with the protective layer 138. The protective layer 140 is formed on the word line 136 along another sidewall 114s2 of the top layer 114, which is opposite to the sidewall 114s1 close to the third gate electrode 124. The protective layers 138 and 140 can reduce the disadvantageous effect due to the divots.

Referring to FIG. 1G, after the protective layer 138 is formed, the cap layer 130 in the periphery region 2000 can be removed. The cap layer 130 may be removed by an oxide-etching step. Since the protective layer 138, as well as the protective layer 140 in some embodiments, is formed, the disadvantageous effect due to the divots of oxide layers will not be so critical as the case without the protective layer.

FIG. 2 shows a semiconductor structure 100 according to one embodiment. Here, the semiconductor structure 100 may be a structure for a split-gate flash. The semiconductor structure comprises, in a cell region 1000, memory cells 200A-200D. Adjacent two of the memory cells, such as memory cells 200A and 200B, are disposed reflectional symmetrically. While four memory cells 200A-200D are shown in FIG. 2, the number of the memory cells is not limited thereto. Typically, the semiconductor structure 100 will comprise a lot of memory cells. For simplify, following description will be focused on the memory cell 200A. The other memory cells, such as memory cells 200B-200D will have substantially the same configuration.

The semiconductor structure 100 comprises a substrate 102, a first gate structure 106, a second gate electrode 108, a third gate electrode 124 and a protective layer 138. The memory cell 200A comprises said first gate structure 106, said second gate electrode 108, said third gate electrode 124 and said protective layer 138.

The substrate 102 may be a substrate of p-type or n-type. The substrate 102 has a first doped region 126, a second doped region 142, and a channel region C between the first doped region 126 and the second doped region 140. The first doped region 126 and the second doped region 142 may be n-type in the case that the substrate 102 is p-type, and vice versa. The channel region C is provided for the conduction of charges between the first doped region 126 and the second doped region 140.

The first gate structure 106 comprises a first gate electrode 110 disposed on the substrate 102 and a first gate dielectric 112 covering the first gate electrode 110. More specifically, the first gate electrode 110 is disposed on and electrically isolated from the channel region C. The second gate electrode 108 is disposed on and electrically isolated from the first gate electrode 110. The first gate structure 106 has an extending portion 106a relative to the second gate electrode 108. More specifically, the extending portion 106a extends beyond a sidewall 108s1 of the second gate electrode 108. The first gate electrode 110 has a protruding portion 110a corresponding to the extending portion 106a of the first gate structure 106 and protruding relative to the second gate electrode 108, so as to provide the corner for enhancing the erase process. The third gate electrode 124 is disposed adjacent to, spatially separated and electrically isolated from the first gate electrode 110 and the second gate electrode 108. The third gate electrode 124 has an extending portion 124a disposed above the extending portion 106a of the first gate structure 106. In the case that the semiconductor structure 100 is a structure for a split-gate flash, the first gate electrode 110 may be functioned as a floating gate, the second gate electrode 108 may be functioned as a control gate, and the third gate electrode 124 may be functioned as an erase gate.

The protective layer 138 is disposed on the third gate electrode 124 and overlaps the extending portion 106a of the first gate structure 106, such that the extending portion 124a of the third gate electrode 124 is positioned between a lower surface 138b of the protective layer 138 and an upper surface 106t of the extending portion 106a of the first gate structure 106. The protective layer 138 may be in direct contact with the third gate electrode 124. The protective layer 138 may comprise silicon nitride (SiN), silicon oxynitride (SiON), silicon carbide (SiC), or silicon carbonitride (SiCN).

The semiconductor structure 100 comprises the first gate dielectric 112 for spatially separateing and electrically isolateing the third gate electrode 124 from the first gate electrode 110. The semiconductor structure 100 may further comprise a second gate dielectric 118, a third gate dielectric 120, and a fourth gate dielectric 122. The second gate dielectric 118 spatially separates and electrically isolates the third gate electrode 124 from the second gate electrode 108. The third gate dielectric 120 spatially separates and electrically isolates the first gate electrode 110 from the substrate 102, particularly from the channel region C of the substrate 102. The fourth gate dielectric 122 spatially separates and electrically isolates the second gate electrode 108 from the first gate electrode 110. The first gate dielectric 112 and the second gate dielectric 118 may comprise oxide. For example, the first gate dielectric 112 and the second gate dielectric 118 may be oxide layers or oxide-nitride-oxide composite layers.

The semiconductor structure 100 may further comprise a top layer 114 disposed on the second gate electrode 108. The top layer 114 may be disposed as a composite layer, such as a nitride-oxide-nitride composite layer. The top layer 114 may comprise the same material of the protective layer 138. Alternatively, an etching rate of the top layer 114 may be substantially the same as an etching rate of the protective layer 138. Here, the etching rate ratio of the top layer 114 to the protective layer 138 may be 0.8 to 1.2, and more specifically, may equal to 1.

The top layer 114 has two opposite sidewalls 114s1 and 114s2, wherein the sidewall 114s1 is the sidewall close to the third gate electrode 124. The protective layer 138 may be disposed along the sidewall 114s1. More specifically, the second gate dielectric 118 extends upward along the sidewall 114s1 between the sidewall 114s1 and the protective layer 138. The protective layer 138 may be in direct contact with the second gate dielectric 118. A total thickness t₁ (shown in FIG. 1F) of the second gate dielectric 118 and the protective layer 138 may be equal to or larger than that a total thickness t₂ (shown in FIG. 1F) of the extending portion 106a of the first gate structure 106, so as to protect the protruding portion 110a of the first gate electrode 110 from damaged by the following process steps in a better way.

The semiconductor structure 100 may further comprise a word line 136. The word line 136 is disposed adjacent to the first gate electrode 110 and the second gate electrode 108 and opposite to the third gate electrode 124. The semiconductor structure 100 may further comprise another protective layer 140, which is disposed on the word line 136 and along the sidewall 114s2 of the top layer 114. The protective layers 138 and 140 can reduce the disadvantage effect due to the divots.

In the semiconductor structure and the manufacturing method therefor according to this invention, a protective layer is formed. As such, the floating gate can be protected by the protective layer from damage due to the manufacturing steps such as ion implantation. In addition, due to the disposition of the protective layer, the disadvantage effect due to the divots of oxide layers will not be so critical. Thus, some of the problems resulted from the decreased device sizes can be prevented.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor structure, comprising:
a substrate;
a first gate structure comprising a first gate electrode disposed on the substrate and a first gate dielectric covering the first gate electrode, the first gate structure having an extending portion;
a second gate electrode disposed on and electrically isolated from the first gate electrode, wherein the extending portion of the first gate structure extends beyond a sidewall of the second gate electrode;
a third gate electrode disposed adjacent to and electrically isolated from the first gate electrode and the second gate electrode, the third gate electrode having an extending portion; and
a protective layer, wherein the extending portion of the third gate electrode being between a lower surface of the protective layer and an upper surface of the extending portion of the first gate structure.

2. The semiconductor structure according to claim 1, wherein the protective layer is in direct contact with the third gate electrode.

3. The semiconductor structure according to claim 1, wherein the protective layer comprises silicon nitride (SiN), silicon oxynitride (SiON), silicon carbide (SiC), or silicon carbonitride (SiCN).

4. The semiconductor structure according to claim 1, further comprising a second gate dielectric isolating the third gate electrode from the second gate electrode, wherein the first gate dielectric isolates the third gate electrode from the first gate electrode, and the first gate dielectric and the second gate dielectric comprise oxide.

5. The semiconductor structure according to claim 1, further comprises:
a top layer disposed on the second gate electrode, the top layer having a sidewall close to the third gate electrode;
wherein the protective layer is disposed along the sidewall of the top layer.

6. The semiconductor structure according to claim 5, further comprising a second gate dielectric isolating the third gate electrode from the second gate electrode, wherein the second gate dielectric extends upward along the sidewall of the top layer between the sidewall of the top layer and the protective layer, and wherein the protective layer is in direct contact with the second gate dielectric.

7. The semiconductor structure according to claim 6, wherein a total thickness of the second gate dielectric and the protective layer is equal to or larger than a total thickness of the extending portion of the first gate structure.

8. The semiconductor structure according to claim 5, wherein the top layer is a composite layer.

9. The semiconductor structure according to claim 5, wherein the top layer having another sidewall opposite to the sidewall close to the third gate electrode, and the semiconductor structure further comprises:
a word line disposed adjacent to the first gate electrode and the second gate electrode and opposite to the third gate electrode; and
another protective layer disposed on the word line and along the another sidewall of the top layer.

10. The semiconductor structure according to claim 1, comprising a first memory cell and a second memory cell, wherein each of the first memory cell and the second memory cell comprises the first gate structure, the second gate electrode, the third gate electrode and the protective layer, and wherein the first memory cell and the second memory cell are disposed reflectional symmetrically.

11. The semiconductor structure according to claim 1, wherein the first gate electrode is functioned as a floating gate, the second gate electrode is functioned as a control gate, and the third gate electrode is functioned as an erase gate.

12. A method for manufacturing a semiconductor structure, the semiconductor structure having a cell region and a periphery region, the method comprising:
providing a substrate;
forming a stack on the substrate in the cell region, the stack comprising a first gate structure and a second gate electrode for a memory cell, wherein the first gate structure comprises a first gate electrode formed on the substrate and a first gate dielectric covering the first gate electrode, the second gate electrode is disposed on the first gate electrode, and the first gate structure has an extending portion extending beyond a sidewall of the second gate electrode;
forming a conductive layer on the substrate, the conductive layer covering the stack;
removing part of the conductive layer to form a third gate electrode adjacent to the first gate structure and the second gate electrode, wherein the third gate electrode has an extending portion; and
forming a protective layer on the third gate electrode such that the extending portion of the third gate electrode is between a lower surface of the protective layer and an upper surface of the extending portion of the first gate structure.

13. The method according to claim 12, wherein the stack further comprises a top layer disposed on the second gate electrode, and the top layer has a sidewall close to the third gate electrode.

14. The method according to claim 13,
wherein at the step of forming the stack, forming a gate dielectric layer comprising the first gate dielectric and extending along the sidewall of the second gate electrode and the sidewall of the top layer;
wherein at the step of removing the part of the conductive layer, the portion of the gate dielectric layer on the sidewall of the top layer is exposed from the conductive layer; and
wherein at the step of forming the protective layer, the protective layer is formed on the exposed portion of the gate dielectric layer.

15. The method according to claim 13, wherein at the step of removing the part of the conductive layer to form the third gate electrode, a word line is formed simultaneously with the third gate electrode, and wherein at the step of forming the protective layer on the third gate electrode, another protective layer is formed on the word line along another sidewall of the top layer that is opposite to the sidewall close to the third gate electrode.

16. The method according to claim 13, wherein the top layer comprises the same material of the protective layer.

17. The method according to claim 13, wherein an etching rate of the top layer is substantially the same as an etching rate of the protective layer.

18. The method according to claim 12, wherein the step of forming the conductive layer comprises:
forming a first conductive layer on the substrate in the cell region and the periphery region, the first conductive layer covering the stack; and
forming a second conductive layer on the first conductive layer in the cell region and the periphery region; and
the method further comprises:
between the step of forming the first conductive layer and the step of forming the second conductive layer, forming a cap layer on the first conductive layer in the periphery region.

19. The method according to claim 18, wherein the step of removing the part of the conductive layer comprises:
planarizing the first conductive layer and the second conductive layer in the cell region and the second conductive layer in the periphery region; and
etching the first conductive layer and the second conductive layer in the cell region; and
the method further comprises:
after the step of forming the protective layer, removing the cap layer in the periphery region.

20. A method for manufacturing a semiconductor structure, comprising:
providing a substrate;
forming a stack on the substrate, the stack comprising a first gate structure and a second gate electrode for a memory cell, wherein the first gate structure comprises a first gate electrode formed on the substrate and a first gate dielectric covering the first gate electrode, the second gate electrode is disposed on the first gate electrode, and the first gate structure has an extending portion extending beyond a sidewall of the second gate electrode;
forming a third gate electrode adjacent to the first gate structure and the second gate electrode, wherein the third gate electrode has an extending portion; and
forming a protective layer on the third gate electrode such that the extending portion of the third gate electrode is between a lower surface of the protective layer and an upper surface of the extending portion of the first gate structure.
